(19) United States
(12) Patent Application Publication
(10) Pub. No.: US 2005/0110069 A1
(43) Pub. Date: May 26, 2005

(54) Hafnium oxide and aluminium oxide alloyed dielectric layer and method for fabricating the same

(75) Inventors: Deok-Sin Kil, Ichon-shi (KR); Jae-Sung Roh, Ichon-shi (KR); Hyun-Chul Sohn, Ichon-shi (KR)

Correspondence Address: Finnegan, Henderson, Farabow,;Garrett & Dunner, L.L.P., 1300 I Street, N.W., Washington, DC, 20005-3315, US

(73) Assignee: HYNIX SEMICONDUCTOR INC.

(21) Appl. No.: 10/819,202

(22) Filed: Apr. 7, 2004

(30) Foreign Application Priority Data
Nov. 22, 2003 (KR) 2003-83398

(51) Int. Cl. H01L 27/108

(52) U.S. Cl. 257/306

(57) ABSTRACT

The present invention relates to a dielectric layer alloyed with hafnium oxide and aluminum oxide and a method for fabricating the same. At this time, the dielectric layer is deposited by an atomic layer deposition technique. The method for fabricating the hafnium oxide and aluminum oxide alloyed dielectric layer includes the steps of: depositing a single atomic layer of hafnium oxide by repeatedly performing a first cycle of an atomic layer deposition technique; depositing a single atomic layer of aluminum oxide by repeatedly performing a second cycle of the atomic layer deposition technique; and depositing a dielectric layer alloyed with the single atomic layer of hafnium oxide and the single atomic layer of aluminum oxide by repeatedly performing a third cycle including the admixed first and second cycles.

### FIELD OF THE INVENTION

The present invention relates to a semiconductor device; and, more particularly, to a dielectric layer of a capacitor and a method for fabricating the same.

Description of Related Arts

Generally, silicon oxide (SiO₂) grown through a thermal process or a rapid thermal process is used as a gate oxide layer of a dynamic random access memory (DRAM) device and a logic device. As a design rule of a semiconductor device has been shifted towards minimization, an effective thickness of the gate oxide layer for a tunneling effect has been decreased to about 25 Å to about 30 Å which is a minimum thickness for the tunneling effect to occur. In devices employing the design rule of about 0.1 μm, an expected thickness of the gate oxide layer ranges from about 25 Å to about 30 Å. However, it is concerned that an increased off-current by a direct tunneling effect may negatively affect operation of the device. Particularly, it is mainly focused in a current memory device to decrease leakage currents.

As an attempt to solve the above problems, it has been vigorously studied on a gate oxide layer made of a material with a high dielectric constant, i.e., a high-k dielectric material. Such materials as tantalum oxide (Ta₂O₅), titanium oxide (TiO₂), aluminum oxide (Al₂O₃) and hafnium oxide (HfO₂) are examples of the high-k dielectric material. In addition, an accelerated integration level of semiconductor memory devices has led to a sharp decrease in a unit cell area. Also, an operation voltage has been decreased to a low level.

However, despite of the decreased cell area, a minimum capacitance required for operating a memory device is greater than about 25 fF/cell in order to prevent incidences of soft error and shortened refresh time. Therefore, a study on the use of a high dielectric material such as Ta₂O₅, TiO₂, Al₂O₃ or HfO₂ having a higher dielectric constant than such materials as silicon oxide (SiO₂), silicon nitride (Si₃N₄) and nitrogen oxide (NO) used as a dielectric layer of a capacitor has actively proceeded in an attempt to obtain a sufficient capacitance required by the large-scale of integration of the semiconductor device. Particularly, a stacked dielectric layer of HfO₂ and Al₂O₃ combined with a good dielectric characteristic provided from the HfO₂ layer and a good leakage current characteristic provided from the Al₂O₃ layer has been currently considered as the most probably applicable dielectric layer of the gate oxide layer and the capacitor.

FIG. 1 is a diagram showing a capacitor structure including a stacked dielectric layer of HfO₂ and Al₂O₃.

As shown, a capacitor includes a lower electrode 11 made of polysilicon, a stacked dielectric layer 12, an upper electrode 13 made of polysilicon. Herein, the stacked dielectric layer 12 is formed by sequentially stacking the Al₂O₃ layer 12A and the HfO₂ layer 12B.

In the stacked dielectric layer 12, the Al₂O₃ layer 12A contacts the lower electrode 11, while the HfO₂ layer 12B contacts the Al₂O₃ layer 12A. Herein, a required thickness of the Al₂O₃ layer 12A is greater than about 20 Å to improve the leakage current characteristic.

A capacitor with the above stacked dielectric layer 12 shows an excellent leakage current characteristic at a low voltage. However, the leakage current abruptly increases at a high voltage, resulting in a low break down voltage. As a result, reliability of the capacitor is further decreased.

FIG. 2 is a graph showing a leakage current characteristic of a conventional capacitor with a stacked dielectric layer formed by stacking a hafnium oxide (HfO₂) layer and an aluminum oxide (Al₂O₃) layer. In FIG. 2, a horizontal axis and a vertical axis express an applied bias and a leakage current, respectively. For measurement of the leakage current, a curve CI is observed in case that an upper electrode is supplied with a positive voltage while a lower electrode is decided to be a ground. On the other hand, a curve CII is observed in cased that an upper electrode is supplied with a negative voltage while a lower electrode is decided to be a ground.

As shown, in a low voltage supply V_{L} condition, the leakage current characteristic shows a gradually decreasing slope. On the other hand, in a high voltage supply V_{H} condition, the leakage current characteristic shows a sharply increasing slope. Because of this sharp increase in the leakage current at the high voltage supply V_{H} condition, there is displayed a low break down voltage in a capacitor.

Also, the HfO₂ layer is formed on the Al₂O₃ layer to secure the dielectric characteristic. However, the HfO₂ layer is thermally unstable, and thus, the leakage current and dielectric characteristics are degraded by a subsequent thermal process proceeding after formation of an upper electrode.

FIG. 3A is a graph showing a leakage current characteristic of a conventional capacitor having only an aluminum oxide (Al₂O₃) layer when the above mentioned subsequent thermal process is performed. FIG. 3B is a graph showing a leakage current characteristic of a conventional capacitor having a stacked dielectric layer of HfO₂ and Al₂O₃ when the above mentioned subsequent thermal process is performed. In FIGS. 3A and 3B, the horizontal axis and the vertical axis express an applied bias and a leakage current, respectively. The curves C1 and C3 show the leakage current characteristic before the subsequent thermal process proceeding after formation of an upper electrode, whereas the curves C2 and C4 show the leakage current characteristic after the thermal process is performed after formation of the upper electrode. Herein, the subsequent thermal process proceeds at a temperature of about 750° C. for about 20 minutes and at another temperature of about 675° C. for about 70 minutes.

Referring to FIG. 3A, the capacitor only with the Al₂O₃ layer shows a consistency in the leakage current characteristic with regardless of the subsequent thermal process. However, the capacitor with the stacked dielectric layer of HfO₂ and Al₂O₃ shows a difference in the leakage current characteristics before and after the subsequent thermal process. More specifically, under the same applied bias, the leakage current obtained after the subsequent thermal process is greater than that obtained before the subsequent thermal process. As shown in FIG. 3B, the leakage current may abruptly increase through a grain boundary of the HfO₂ crystallized by the subsequent thermal process.

### SUMMARY OF THE INVENTION

It is, therefore, an object of the present invention to provide a dielectric layer of a semiconductor device capable of preventing a break down voltage from being lowered at a high supply voltage when a dielectric layer is formed by sequentially stacking a hafnium oxide (HfO₂) layer and an aluminum oxide (Al₂O₃) layer and a method for fabricating the same.

It is another object of the present invention to provide a dielectric layer of a semiconductor device capable of preventing an increase in leakage current during a subsequent thermal process caused by a hafnium oxide (HfO₂) and aluminum oxide (Al₂O₃) stacked dielectric layer.

In accordance with an aspect of the present invention, there is provided a dielectric layer of a semiconductor device, including a hafnium oxide and aluminum oxide alloyed dielectric layer through the use of an atomic layer deposition technique.

In accordance with another aspect of the present invention, there is also provided a method for fabricating a dielectric layer of a semiconductor device, including the steps of: depositing a single atomic layer of hafnium oxide by repeatedly performing a first cycle of an atomic layer deposition technique; depositing a single atomic layer of aluminum oxide by repeatedly performing a second cycle of the atomic layer deposition technique; and depositing a dielectric layer alloyed with the single atomic layer of hafnium oxide and the single atomic layer of aluminum oxide by repeatedly performing a third cycle including the mixed first and second cycles.

In accordance with still another aspect of the present invention, there is also provided a method for fabricating a dielectric layer alloyed with hafnium oxide and aluminum oxide, including the step of repeatedly performing a unit cycle of sequentially providing a single molecular source gas of hafnium and aluminum, a purging gas, an oxidation agent, and a purge gas.

### BRIEF DESCRIPTION OF THE DRAWINGS

The above and other objects and features of the present invention will become better understood with respect to the following description of the preferred embodiments given in conjunction with the accompanying drawings, in which:

FIG. 1 is a diagram showing a structure of a capacitor having a conventional hafnium oxide (HfO₂) and aluminum oxide (Al₂O₃) stacked dielectric layer;

FIG. 2 is a graph showing a leakage current characteristic of a capacitor having a conventional hafnium oxide (HfO₂) and aluminum oxide (Al₂O₃) stacked dielectric layer;

FIG. 3A is a graph showing a leakage current characteristic of a capacitor having only a conventional aluminum oxide (Al₂O₃) dielectric layer during a subsequent thermal process;

FIG. 3B is a graph showing a leakage current characteristic of a capacitor having a conventional hafnium oxide (HfO₂) and aluminum oxide (Al₂O₃) stacked dielectric layer during a subsequent thermal process;

FIG. 4 is a diagram showing a dielectric layer alloyed with hafnium oxide (HfO₂) and aluminum oxide (Al₂O₃) in accordance with a first preferred embodiment of the present invention;

FIG. 5 is a timing diagram showing gas supply to a chamber when the HfO₂ and Al₂O₃ alloyed dielectric layer is formed by employing an atomic layer deposition (ALD) technique in accordance with the first preferred embodiment of the present invention;

FIG. 6 is a diagram showing an HfO₂ and Al₂O₃ alloyed dielectric layer in accordance with a second preferred embodiment of the present invention;

FIG. 7A is a timing diagram showing gas supply to a chamber when the HfO₂ and Al₂O₃ alloyed dielectric layer is formed by employing an ALD technique in accordance with the second preferred embodiment of the present invention;

FIG. 7B is a diagram showing an alloyed state of (HfO₂)₁₋ₓ(Al₂O₃)ₓ formed by a reaction between a single molecular source gas of Hf—Al and a reaction gas of ozone (O₃); and

FIG. 8 is a graph showing leakage current characteristics of a HfO₂ and Al₂O₃ stacked dielectric layer, a [A/H/A/H/A/H/A/H/A] laminated dielectric layer and a [HOAOAO] alloyed dielectric layer of a capacitor, in which ‘A’, ‘H’ and ‘O’ represent atoms or molecules.

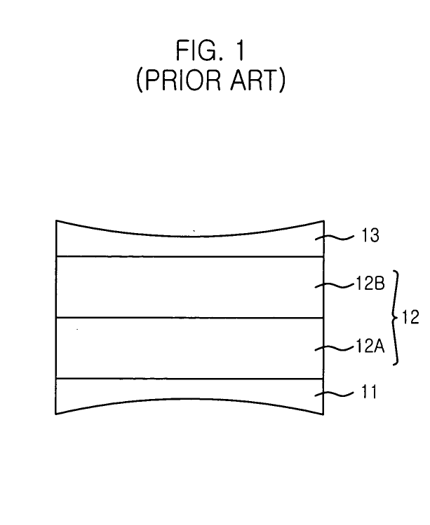

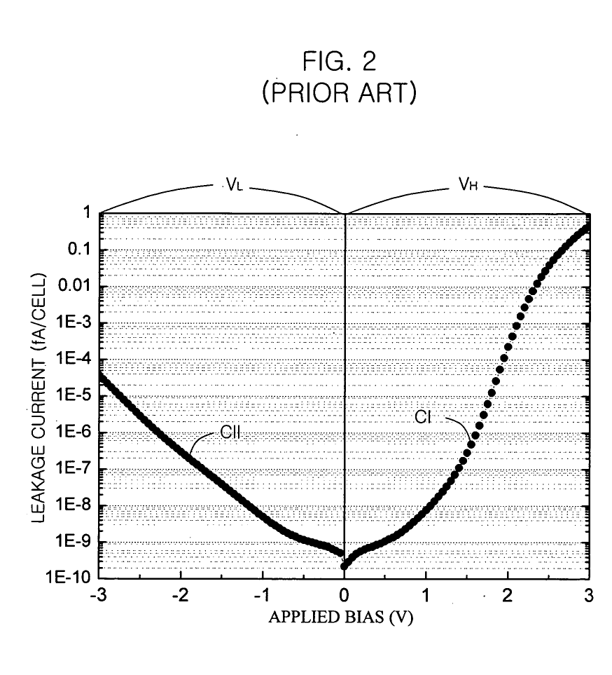

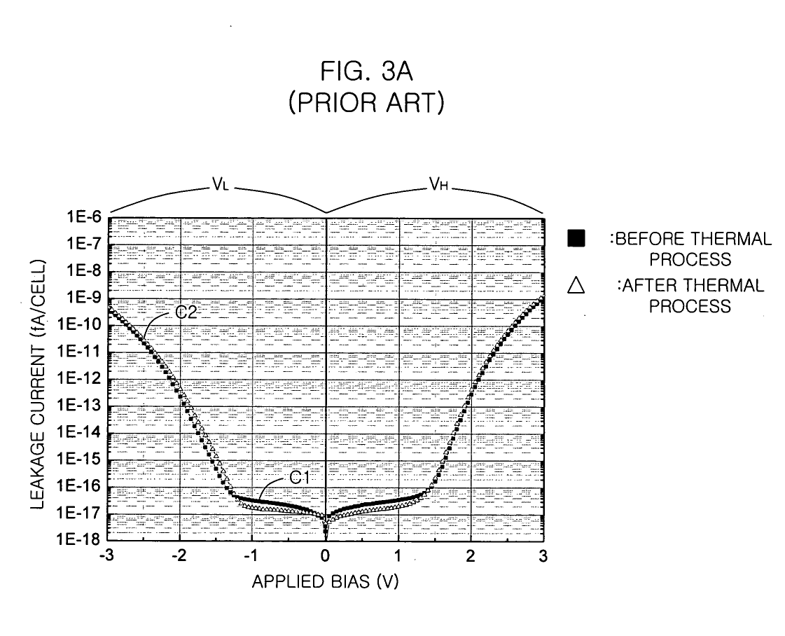

### DETAILED DESCRIPTION OF THE INVENTION

Hereinafter, preferred embodiments of the present invention will be described in detail with reference to the accompanying drawings.

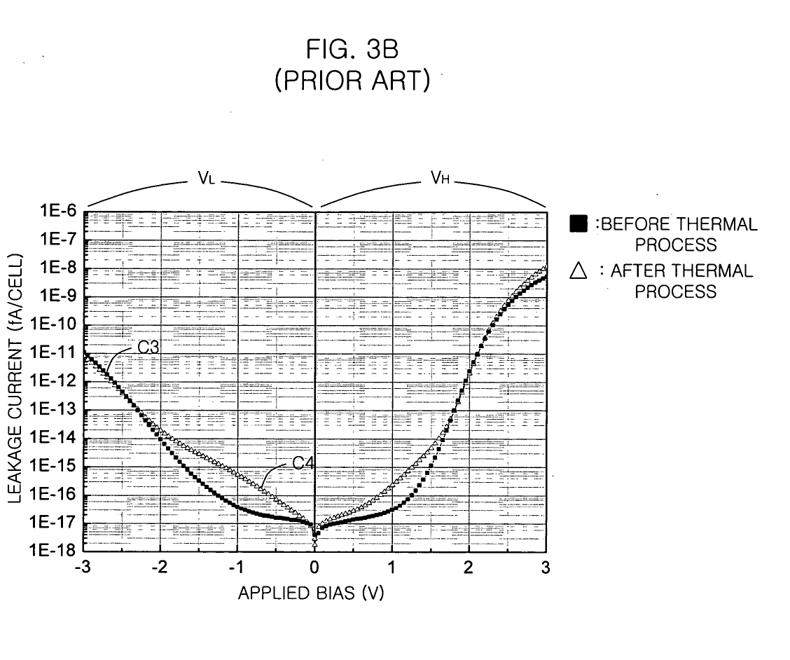

FIG. 4 is a diagram showing a dielectric layer alloyed with hafnium oxide (HfO₂) and aluminum oxide (Al₂O₃) in accordance with a first preferred embodiment of the present invention.

As shown, a dielectric layer 20 is formed by alloying aluminum oxide (Al₂O₃) 21 and hafnium oxide (HfO₂) 22 together, so that the dielectric layer 20 has a molecular structure of (HfO₂)₁₋ₓ(Al₂O₃)ₓ, in which x represents a molecular composition ratio.

Particularly, the dielectric layer 20 is deposited by using an atomic layer deposition (ALD) technique. For instance, a cycle of depositing the Al₂O₃ 21 in a unit of an atomic layer is repeatedly performed, and then, a cycle of depositing the HfO₂ 22 in a unit of an atomic layer is repeatedly performed. Thereafter, a mixed cycle of the above two cycles is then continuously repeated until a required thickness of the hafnium oxide (HfO₂) and aluminum oxide (Al₂O₃) is reached.

Also, it is shown in FIG. 4 that the Al₂O₃ 21 and the HfO₂ 22 are formed in one layer. The reason for this simultaneous formation of the Al₂O₃ 21 and the HfO₂ 22 in one layer is because of a characteristic of the atomic layer deposition technique which allows a single atomic layer to be formed inconsecutively by controlling the number of the cycles. That is, a single atomic layer of the Al₂O₃ 21 is deposited inconsecutively if the cycle is repeatedly performed with the less number of times. Hereinafter, the Al₂O₃ and HfO₂ 21 and 22 each formed in a unit of an atomic layer are referred to as the Al₂O₃ layer and the HfO₂ layer, respectively.

In more detail of a method for forming the dielectric layer 20 with a structure of (HfO₂)₁₋ₓ(Al₂O₃)ₓ, an ALD technique is used to form the Al₂O₃ layer 21 and the HfO₂ layer 22 in a single layer. At this time, the number of repeating each cycle for forming individually the Al₂O₃ layer 21 and the HfO₂ layer 22 is controlled to obtain an intended thickness of the Al₂O₃ layer 21 and the HfO₂ layer 22 ranging from about 1 Å to about 10 Å. Herein, the above thickness is the thickness of each inconsecutively formed single layer of the Al₂O₃ 21 and the HfO₂ 22. If the thickness of each single layer is greater than about 10 Å, the consecutive atomic layer is formed, thereby resulting in a stacked structure instead of an alloyed structure.

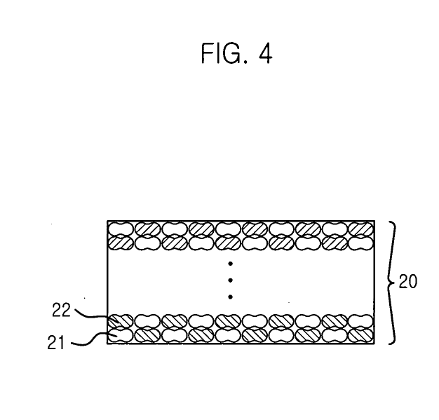

FIG. 5 is a timing diagram showing gas supply to a chamber when the dielectric layer 20 having the molecular structure of (HfO₂)₁₋ₓ(Al₂O₃)ₓ is formed by employing the ALD technique in accordance with the first preferred embodiment of the present invention.

As known, a source gas is first supplied to a chamber to make the source gas molecules chemically adsorbed onto a surface of a substrate. Then, those physically adsorbed source gas molecules are purged out by applying a purge gas. A reaction gas is supplied thereto to make the chemically adsorbed source gas molecules react with the reaction gas. From this chemical reaction, a single atomic layer is deposited. Thereafter, the non-reacted reaction gas is purged out by using a purge gas. The above sequential steps constitute one cycle of the single atomic layer deposition. The above ALD technique adopts a surface reaction mechanism to provide a stable and uniform thin layer. Also, compared to a chemical mechanical deposition (CVD) technique, the ALD technique effectively prevents particle generations caused by a gas phase reaction since the source gas and the reaction gas are separately provided in order and are purged out thereafter.

The above mentioned unit cycle for depositing the dielectric layer 20 with a molecular structure of (HfO₂)₁₋ₓ(Al₂O₃)ₓ will be described in more detail.

The unit cycle can be expressed as follows.
[(Hf/N₂/O₃/N₂)_{y}(Al/N₂/O₃/N₂)_{z}]ₙ Unit cycle 1.
Herein, Hf and Al are source gases for forming the HfO₂ layer 22 and the Al₂O₃ layer 21, respectively. The subscripts ‘y’ and ‘z’ represent the number of repeating a respective cycle of (Hf/N₂/O₃/N₂) and (Al/N₂/O₃/N₂). Another subscript ‘n’ represents the number of repeating the [(Hf/N₂/O₃/N₂)_{y}(Al/N₂/O₃/N₂)_{z}] cycle. Herein, ‘y’, ‘z’ and ‘n’ are natural numbers.

More specific to the unit cycle 1, the (Hf/N₂/O₃/N₂)_{y} cycle expresses sequential steps of providing a source gas of hafnium (Hf), a purge gas of nitrogen (N₂), an oxidation agent of ozone (O₃), and a purge gas of nitrogen (N₂), and this cycle is repeatedly performed y times. Also, the (Al/N₂/O₃/N₂)_{z} cycle expresses sequential steps of providing a source gas of aluminum (Al), a purge gas of N₂, an oxidation agent of O₃, and a purge gas of N₂, and this cycle is repeatedly performed z times. These cycles are repeated y and z times to respectively deposit a single layer of HfO₂ 22 and Al₂O₃ 21 with an intended thickness.

For the single atomic layer deposition of the Al₂O₃ 21, a source gas of trimethylaluminum (Al(CH₃)₃) maintained with a room temperature is first flowed into a chamber for about 0.1 seconds to about 3 seconds. Hereinafter, trimethylaluminum is referred to as TMA. At this time, the chamber is maintained with a temperature ranging from about 200° C. to about 350° C. and a pressure ranging from about 0.1 torr to about 10 torr. The TMA source gas molecules are adsorbed onto a lower electrode. Thereafter, a purge gas of N₂ is flowed into the chamber for about 0.1 seconds to about 5 seconds to remove the chemically unadsorbed TMA source gas molecules. Then, an oxidation agent of O₃, which is a reaction gas, is flowed into the chamber for about 0.1 seconds to about 3 seconds to induce a reaction between the adsorbed TMA source gas molecules and the O₃ gas molecules. As a result of the above reaction, an atomic layer of the Al₂O₃ 21 is deposited. Next, a purge gas of N₂ is flowed into the chamber for about 0.1 seconds to about 5 seconds to purge out the non-reacted O₃ molecules and byproducts of the above reaction.

The above described sequential steps of providing the TMA source gas, the purge gas of N₂, the reaction gas of O₃, and the purge gas of N₂ constitute one unit cycle which is repeatedly performed z times to deposit the Al₂O₃ layer 21 with an intended thickness. Herein, in addition to the TMA, modified TMA (MTMA; Al(CH)₃N(CH₂)₅CH₃) can be used as the source gas of Al. In addition to the O₃ gas, water (H₂O) and oxygen (O₂) plasma can be used as the oxidation agent. Such inert gas as argon (Ar) can be used as the purge gas as well.

For the single atomic layer deposition of the HfO₂ 22, a source gas selected from a group consisting of HfCl₄, Hf(NO₃)₄, Hf(NCH₃C₂H₅)₄, Hf[N(CH₃)₂]₄ and Hf[N[C₂H₅)₂]₄ is vaporized at a vaporizer and is flowed into a chamber maintained with a temperature ranging from about 200° C. to about 400° C. and a pressure ranging from about 0.1 torr to about 10 torr to thereby make the Hf source gas molecules adsorbed. A purge gas of N₂ is then flowed into the chamber for about 0.1 seconds to about 5 seconds to purge out the unadsorbed Hf source gas molecules. A reaction gas of O₃ is flowed into the chamber for about 0.1 seconds to about 3 seconds to induce a reaction between the adsorbed Hf source molecules and the O₃ gas molecules. From this induced reaction, a single atomic layer of the HfO₂ 22 is deposited. Next, a purge gas of N₂ is flowed into the chamber for about 0.1 seconds to about 5 seconds to purge out the non-reacted O₃ gas molecules and byproducts of the above reaction.

The sequential steps of providing the Hf source gas, the purge gas of N₂, the reaction gas of O₃ and the purge gas of N₂ constitutes one unit cycle which is repeatedly performed y times to deposit the HfO₂ layer 22 with an intended thickness. In addition to the O₃ gas, H₂O and oxygen plasma can be used as the oxidation agent. Such inert gas as Ar can be used as the purge gas as well.

It is well known that the above ALD technique proceeds in a pulse-like unit. The above unit cycle 1 is repeated to form the dielectric layer 20 in a molecular structure of (HfO₂)₁₋ₓ(Al₂O₃)ₓ, wherein the HfO₂ layer 22 and the Al₂O₃ layer 21 are uniformly formed in a predetermined molecular composition ratio.

There are conditions to form such dielectric layer 20 with the molecular structure of (HfO₂)₁₋ₓ(Al₂O₃)ₓ. First, the unit cycle 1 including the cycle of (Hf/N₂/O₃/N₂) repeatedly performed y times and the cycle of (Al/N₂/O₃/N₂) repeatedly performed z times is repeated n times. However, the number of repeating each of the two cycles, i.e., y and z, is specifically controlled such that the thickness of the HfO₂ layer 22 formed by the cycle of (Hf/N₂/O₃/N₂) and that of the Al₂O₃ layer 21 formed by the cycle of (Al/N₂/O₃/N₂) range from about 1 Å to about 10 Å in order to maximize an effect of uniformly alloying the HfO₂ layer 22 and Al₂O₃ layer 21. If the thickness of each single atomic layer is greater than about 10 Å, each single atomic layer shows a characteristic of consecutiveness, resulting in the same conventional stacked dielectric layer of HfO₂ and Al₂O₃ or even more a degraded dielectric characteristic.

Second, the ratio of repeating the number of the two cycles, i.e., y and z, needs to be controlled appropriately to make the Al₂O₃ layer 21 in a ratio ranging from about 30% to about 60% in order to obtain an excellent electric characteristic by forming an amorphous thin dielectric layer through the alloying of the HfO₂ layer 22 and Al₂O₃ layer 21.

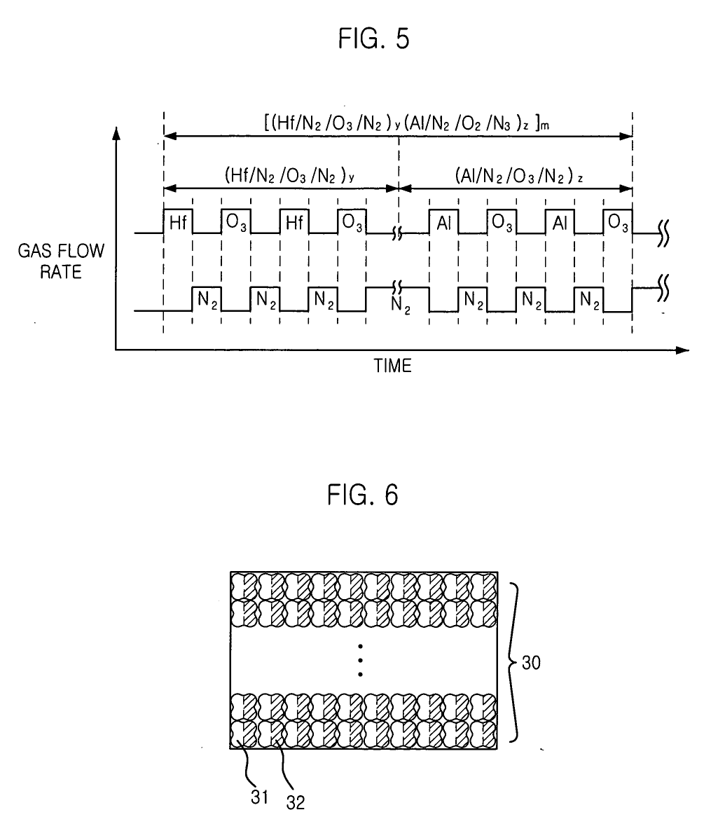

FIG. 6 is a diagram showing a dielectric layer alloyed with HfO₂ and Al₂O₃ in accordance with a second preferred embodiment of the present invention.

As shown, a dielectric layer 30 is formed by uniformly alloying Al₂O₃ 31 and HfO₂ 32 together, so that the dielectric layer 30 has a molecular structure of (HfO₂)₁₋ₓ(Al₂O₃)ₓ, in which x represents a molecular composition ratio. Herein, the dielectric layer 30 is deposited by employing an ALD technique.

Unlike the dielectric layer 20 in FIG. 4, the dielectric layer 30 has a differently alloyed structure of the Al₂O₃ and HfO₂ because a single molecular source gas of Al and Hf is used for the deposition of the dielectric layer 30. Another type of the unit cycle using the above mentioned single molecular source gas of Al and Hf is performed to form the dielectric layer 30. This unit cycle can be expressed as follows.
[(Hf—Al)/N₂/O₃/N₂]_{w} Unit cycle 2.
Herein, Hf—Al represents a singe molecular source gas, wherein Hf and Al are admixed to exist in a single molecule. Such substance as HfAl(MMP)₂(OiPr)₅ is an example of the single molecular source gas of Hf and Al. Herein, MMP and OiPr represent methylthiopropionaldehyde and isopropoxides, respectively.

In the first preferred embodiment, the Hf source gas and the Al source gas are individually supplied as described in the unit cycle 1 of FIG. 5. However, in the second preferred embodiment, the single molecular source gas of Hf and Al is used as shown in the unit cycle 2. This use of the single molecular source gas simplifies the steps of supplying the source gas and further shortens an overall period of the whole cycle. It is possible to control the Hf and Al composition ratio by controlling a ratio of each Hf and Al when Hf and Al are admixed to form a single molecule.

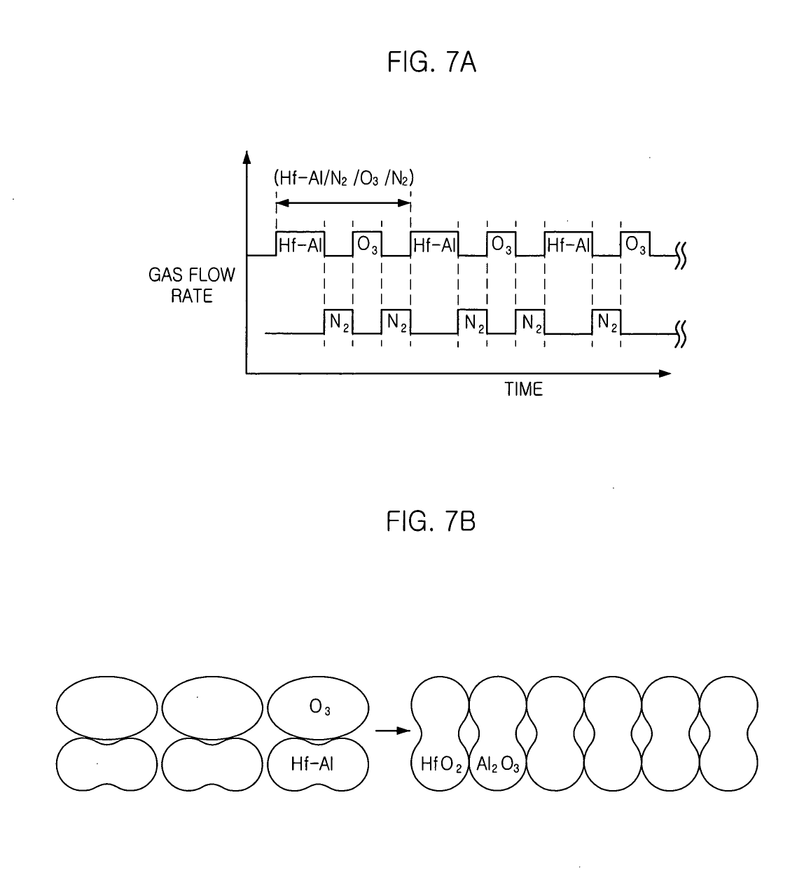

FIG. 7A is a timing diagram showing gas supply into a chamber to form the dielectric layer 30 in a molecular structure of the (HfO₂)₁₋ₓ(Al₂O₃)ₓ through the ALD technique in accordance with the second preferred embodiment of the present invention. FIG. 7B is a diagram showing the above mentioned molecular structure of (HfO₂)₁₋ₓ(Al₂O₃)ₓ formed based on a reaction between the single molecular source gas of Hf—Al and the reaction gas of O₃.

Referring to FIG. 7A, the cycle of (Hf—Al/N₂/O₃/N₂)_{w} refers to sequential steps of providing the single molecular source gas of Hf—Al, the purge gas of N₂, the oxidation agent of O₃, which is the reaction gas, and the purge gas of N₂. This cycle is repeated w times until a required thickness of the dielectric layer 30 having the molecular structure of (HfO₂)₁₋ₓ(Al₂O₃)ₓ is reached. Herein, ‘w’ is a natural number.

The above mentioned cycle of the ALD technique will be described in more detail. First, the source gas, e.g., HfAl(MMP)₂(OiPr)₅, maintained with a room temperature is flowed into a chamber for about 0.1 seconds to about 3 seconds to make the source gas molecules of HfAl(MMP)₂(OiPr)₅ adsorbed. At this time, the chamber is maintained with a temperature ranging from about 200° C. to about 350° C. and a pressure ranging from about 0.1 torr to about 10 torr. Next, the purge gas of N₂ is flowed into the chamber for about 0.1 seconds to about 5 seconds to eliminate the non-adsorbed HfAl(MMP)₂(OiPr)₅ molecules. Thereafter, the reaction gas of O₃ is flowed for about 0.1 seconds to about 3 seconds to induce a reaction between the adsorbed HfAl(MMP)₂(OiPr)₅ molecules and the supplied O₃ gas. From this reaction, an atomic layer of (HfO₂)₁₋ₓ(Al₂O₃)ₓ constituted with the HfO₂ layer 32 and the Al₂O₃ layer 31 is deposited. The purge gas of N₂ is again flowed into the chamber for about 0.1 seconds to about 5 seconds to purge out the non-reacted O₃ gas and byproducts of the reaction. The above described structure of (HfO₂)₁₋ₓ(Al₂O₃)ₓ is shown in FIG. 7B.

The above unit cycle 2 including sequential steps of providing the source gas of HfAl(MMP)₂(OiPr)₅, the purge gas of N₂, the reaction gas of O₃ and the purge gas of N₂ is repeated w times until an intended thickness of the HfO₂ and Al₂O₃ alloyed dielectric layer 30 is reached. Meanwhile, in addition to the O₃ gas, H₂O and oxygen plasma can be used as the oxidation agent. Such inert gas as Ar can also be used as the purge gas as well.

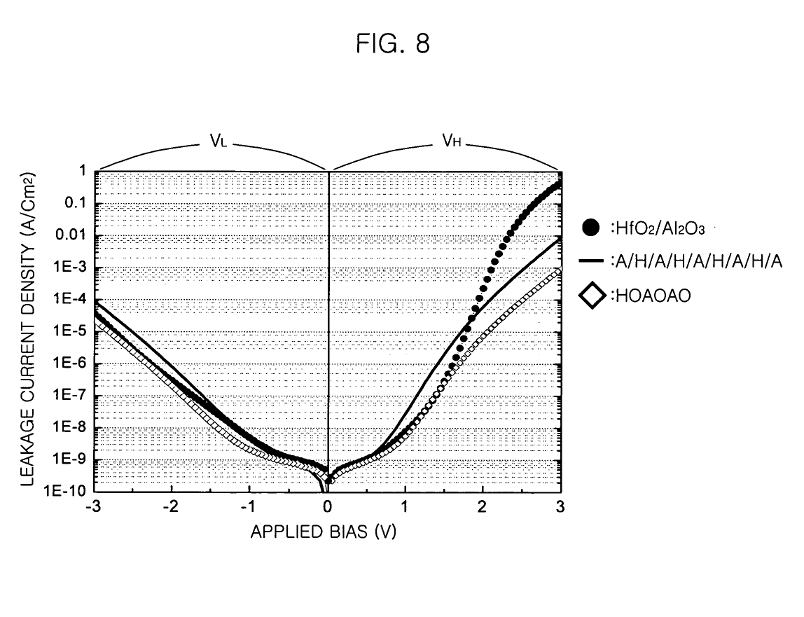

FIG. 8 is a graph showing leakage current characteristics of an HfO₂/Al₂O₃ stacked dielectric layer, a [A/H/A/H/A/H/A/H/A] laminated layer and a [HOAOAO] alloyed layer. The leakage current characteristics are obtained when the above listed layers are applied as a dielectric layer of a capacitor. Herein, ‘A’, ‘H’ and ‘O’ represent atoms or molecules employed to form a specific structure of the intended layer.

As shown, the HfO₂ and Al₂O₃ stacked dielectric layer is formed by stacking HfO₂ and Al₂O₃ with a respective thickness of about 20 Å and of about 25 Å. The [A/H/A/H/A/H/A/H/A] laminated layer is formed by alternatively stacking Al₂O₃ and HfO₂ each with a thickness of about 10 Å. The [HOAOAO] alloyed layer is formed by performing the unit cycle of (Hf/N₂/O₃/N₂)₁(Al/N₂/O₃/N₂)₂ in accordance with the first preferred embodiment of the present invention.

More specific to the leakage current characteristics of the above mentioned layers in FIG. 8, the [HOAOAO] alloyed layer formed on the basis of the first preferred embodiment shows a low leakage current characteristic in a low voltage supply V_{L} condition just like the HfO₂ and Al₂O₃ stacked dielectric layer due to a contact characteristic of the Al₂O₃ layer. Also, the [HOAOAO] alloyed layer exhibits a high take-off voltage characteristic in the low voltage supply V_{L} condition. Herein, the take-off voltage is a voltage wherein a leakage current sharply increases. However, the [HOAOAO] alloyed layer shows a high break down voltage characteristic in a high voltage supply V_{H} condition due to a pronounced contact characteristic of the HfO₂ layer over that of the Al₂O₃ layer. That is, in the high voltage supply V_{H} condition, leakage currents of the [HOAOAO] alloyed layer increase in a gradual slope. Contrary to the [HOAOAO] alloyed layer, leakage currents of the HfO₂/Al₂O₃ stacked dielectric layer and the [A/H/A/H/A/H/A/H/A] laminated layer sharply increase in a steep slope. Also, under the identical high voltage supply V_{H} condition, the [HOAOAO] alloyed layer has a low leakage current density compared to the other layers.

The above characteristic leakage current behavior of the [HOAOAO] alloyed layer even in the high voltage supply V_{H} condition is because a defect with negative charges typically existing in the Al₂O₃ layer and a defect with positive charges typically existing in the HfO₂ layer are offset against each other. Therefore, compared to the HfO₂ and Al₂O₃ stacked dielectric layer, the [HOAOAO] alloyed dielectric layer shows an excellent leakage current characteristic in both of the low voltage supply V_{L} condition and the high voltage supply V_{H} condition.

Also, in the [HOAOAO] alloyed layer, a direct contact of the HfO₂ layer to an upper electrode and a lower electrode is minimized, and thereby suppressing degradation of the leakage current and dielectric characteristics by a thermal process performed after formation of the upper electrode.

On the basis of the first and the second preferred embodiments of the present invention, it is possible to fabricate a high quality of a dielectric layer with a high dielectric constant as well as with a high break down voltage characteristic and a good leakage current characteristic.

It should be noted that the dielectric layers formed by the first and the second preferred embodiments of the present invention are applicable only as a gate oxide layer or a dielectric layer of a capacitor.

The present application contains subject matter related to the Korean patent application No. KR 2003-0083398, filed in the Korean Patent Office on Nov. 22, 2003, the entire contents of which being incorporated herein by reference.

While the present invention has been described with respect to certain preferred embodiments, it will be apparent to those skilled in the art that various changes and modifications may be made without departing from the scope of the invention as defined in the following claims.

1. A dielectric layer of a semiconductor device, comprising a hafnium oxide and aluminum oxide alloyed dielectric layer through the use of an atomic layer deposition technique.

2. The dielectric layer as recited in claim 1, wherein the hafnium oxide and the aluminum oxide are HfO₂ and Al₂O₃, respectively and the hafnium oxide and aluminum oxide alloyed dielectric layer has a molecular structure of (HfO₂)₁₋ₓ(Al₂O₃)ₓ, in which x represents a molecular composition ratio.

3. The dielectric layer as recited in claim 2, wherein each of the HfO₂ layer and the Al₂O₃ layer has a thickness ranging from about 1 Å to about 10 Å.

4. The dielectric layer as recited in claim 2, wherein in the molecular structure of (HfO₂)₁₋ₓ(Al₂O₃)ₓ, the subscript x representing a molecular composition ratio of the Al₂O₃ layer ranges from about 0.3 to about 0.6.

5. A method for fabricating a dielectric layer of a semiconductor device, comprising the steps of:
depositing a single atomic layer of hafnium oxide by repeatedly performing a first cycle of an atomic layer deposition technique;
depositing a single atomic layer of aluminum oxide by repeatedly performing a second cycle of the atomic layer deposition technique; and
depositing a dielectric layer alloyed with the single atomic layer of hafnium oxide and the single atomic layer of aluminum oxide by repeatedly performing a third cycle including the mixed first and second cycles.

6. The method as recited in claim 5, wherein the single atomic layer of hafnium oxide and the single atomic layer of aluminum oxide are an HfO₂ layer and an Al₂O₃ layer, respectively and the hafnium oxide and aluminum oxide alloyed dielectric layer has a molecular structure of (HfO₂)₁₋ₓ(Al₂O₃)ₓ, in which x represents a molecular composition ratio.

7. The method as recited in claim 6, wherein each of the HfO₂ layer and the Al₂O₃ layer has a thickness ranging from about 1 Å to about 10 Å.

8. The method as recited in claim 6, wherein a ratio of the first cycle and the second cycle is controlled to make the subscript x representing the molecular ratio of the Al₂O₃ layer range from about 0.3 to about 0.6.

9. The method as recited in claim 5, wherein the first cycle is a unit cycle constituted with sequential steps of providing a source gas of hafnium, a purge gas, an oxidation agent and a purge gas.

10. The method as recited in claim 6, wherein the first cycle is a unit cycle constituted with sequential steps of providing a source gas of hafnium, a purge gas, an oxidation agent and a purge gas.

11. The method as recited in claim 9, wherein the source gas of hafnium is selected from a group consisting of HfCl₄, Hf (NO₃)₄, Hf (NCH₃C₂H₅)₄, Hf[N(CH₃)₂]₄ and Hf[N(C₂H₅)₂]₄; the oxidation agent is one of O₃ and H₂O and O₂ plasma; and the purge gas is one of N₂ and Ar.

12. The method as recited in claim 10, wherein the source gas of hafnium is selected from a group consisting of HfCl₄, Hf(NO₃)₄, Hf(NCH₃C₂H₅)₄, Hf[N(CH₃)₂]₄ and Hf[N(C₂H₅)₂]₄; the oxidation agent is one of O₃ and H₂O and O₂ plasma; and the purge gas is one of N₂ and Ar.

13. The method as recited in claim 5, wherein the second cycle is a unit cycle constituted with sequential steps of providing a source gas of aluminum, a purge gas, an oxidation agent, and a purge gas.

14. The method as recited in claim 6, wherein the second cycle is a unit cycle constituted with sequential steps of providing a source gas of aluminum, a purge gas, an oxidation agent, and a purge gas.

15. The method as recited in claim 13, wherein the source gas of aluminum is one of trimethylaluminum (TMA) and modified TMA (MTMA); the oxidation agent is one of O₃ and H₂O and O₂ plasma; and the purge gas is one of N₂ and Ar.

16. The method as recited in claim 14, wherein the source gas of aluminum is one of TMA and MTMA; the oxidation agent is one of O₃ and H₂O and O₂ plasma; and the purge gas is one of N₂ and Ar.

17. A method for fabricating a dielectric layer alloyed with hafnium oxide and aluminum oxide, the method comprising the step of repeatedly performing a unit cycle of sequentially providing a single molecular source gas of hafnium and aluminum, a purging gas, an oxidation agent, and a purge gas.

18. The method as recited in claim 17, wherein nomenclatures of the hafnium oxide and the aluminum oxide are HfO₂ and Al₂O₃, respectively and the hafnium oxide and aluminum oxide alloyed dielectric layer has a molecular structure of (HfO₂)₁₋ₓ(Al₂O₃)ₓ, in which x represents a molecular composition ratio.

19. The method as recited in claim 17, wherein the single molecular source gas of hafnium and aluminum is HfAl(MMP)₂(OiPr)₅; the oxidation agent is one of O₃ and H₂O and O₂ plasma; and the purge gas is one of N₂ and Ar.
